(19) United States
(12) Patent Application Publication
(10) Pub. No.: US 2020/0025809 A1
(43) Pub. Date: Jan. 23, 2020

(54) DESTRUCTIVE CURRENT CONDITIONS PROTECTIVE SYSTEM AND METHOD

(71) Applicants: Karol Renau, Calabasas, CA (US); Roman Pyrzynski, Simi Valley, CA (US)

(72) Inventors: Karol Renau, Calabasas, CA (US); Roman Pyrzynski, Simi Valley, CA (US)

(21) Appl. No.: 16/038,008

(22) Filed: Jul. 17, 2018

(51) Int. Cl. G01R 19/30; G01R 19/165; H02H 3/08; H02H 3/02

(52) U.S. Cl. CPC G01R 19/30; H02H 3/021; H02H 3/08; G01R 19/165

(57) ABSTRACT

Systems and methods for protecting a device from destructive current flowing through the device, including protecting the device from overload current and short circuit current. Time limiting elements in the system enable rapid response to a destructive current condition to limit the time of the destructive current condition. Maximum current limiting elements in the system enable rapid response to a destructive current condition to limit the maximum current of the destructive current condition.

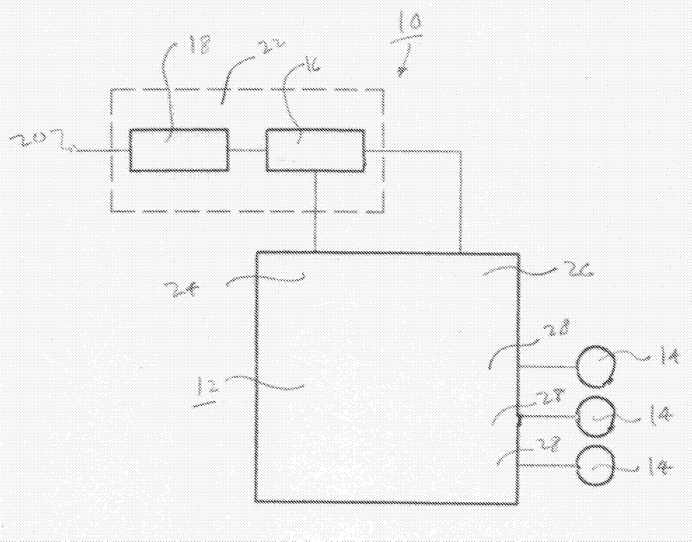

### COPYRIGHTABLE SUBJECT MATTER

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### BACKGROUND OF THE INVENTION

### 1. Field of the Invention

This invention is generally related to current protection systems and methods, and more particularly, to systems and methods for protecting devices against destructive current conditions.

### 2. General Background and State of the Art

In an electric power system, over-current or excess current can take place when a larger than intended electric current exists through a conductor, leading to excessive generation of heat, and the risk of damage or fire to equipment.

Possible causes for overload current include short circuits, excessive load, incorrect design, or a ground fault.

In an improper installation, the current from a short circuit may cause heating of the circuit parts with poor conductivity, such as faulty joints in wiring, faulty contacts in power sockets, or even the site of the short circuit itself. Such overheating may cause of fires. An electric arc, if it forms during the short circuit, can produce a high amount of heat and can cause ignition of combustible substances as well.

A short circuit in an electrical circuit can occur when a current travels along an unintended path with no or a very low electrical impedance.

Abnormal connection between two nodes of an electric circuit intended to be at different voltages may generate a short circuit that forces them to be at the same voltage. This results in an excessive electric current limited only by the resistance of the rest of the circuit, and potentially causes circuit damage, overheating, fire or explosion.

A short circuit may lead to formation of an electric arc. The arc, a channel of hot ionized plasma, is highly conductive and can persist even after a significant amount of original material of conductors has evaporated. Surface erosion is a sign of electric arc damage. Even short arcs can remove significant amount of materials from the electrodes. The temperature of the resulting electrical arc may be very high, causing the metal on the contact surfaces to melt, pool and migrate with the current, as well as to escape into the air as fine particulate matter.

For protection against the risks of overload current, fuses, circuit breakers, temperature sensors and current limiters have been used.

Damage from over-currents and short circuits has been reduced or prevented by employing fuses, circuit breakers, or other overload protection, which disconnect the power in reaction to excessive current. Overload protection must be chosen according to the current rating of the circuit. An overload current protection device may be rated to safely interrupt the maximum prospective short circuit current.

A circuit breaker is an automatically operated electrical switch designed to protect an electrical circuit from damage caused by excess current, typically resulting from an overload or short circuit. Its basic function is to interrupt current flow after a fault is detected. Unlike a fuse, which operates once and then must be replaced, a circuit breaker can be reset to resume normal operation. Circuit breakers are made in varying sizes, including small devices that protect low-current circuits or individual household appliance. The generic function of a circuit breaker or a fuse is as an automatic means of removing power from a faulty system.

External fuses and circuit breakers which have been used are not fast enough to prevent damage in short circuit and other conditions.

For loads connected in an electrical circuit, the voltage, frequency and amount of power supplied to the loads should be in line with expectations, and protecting the load from overload currents and short circuits are among the great challenges.

Another issue for loads has to do with power quality. In particular, sustained over-voltages in power system loads can be adversely affected by a range of temporal issues.

The types and ranges of destructive over-current protection elements that will protect against destructive over-current conducting in the event of overload and short circuit condition in a specific end application depends on the end application.

Destructive overload current conducting can be caused by failure of the high voltage component of a device, such as a heater, a valve, a motor, or the like, which results in a very high current.

End applications such as foodservice equipment, which equipment includes controllers and high voltage solid state switching elements, need protection against over-current and short circuits, and continuous current monitoring, to prevent current which exceeds the maximum allowed ratings from passing through. Relays such as solid state relays and relay switches have been included in such equipment, which are large and expensive, which provide limited current monitoring capability, reliability, and equipment life, and which increase end user labor, maintenance and inventory costs.

Therefore, there has been identified a continuing need to provide systems and methods for protecting equipment against destructive current conditions more effectively and safely, to improve equipment reliability, to continuously monitor current conditions, and to reduce equipment labor, maintenance and inventory costs.

### INVENTION SUMMARY

Briefly, and in general terms, in accordance with aspects of the invention, and in a preferred embodiment, by way of example, there are provided systems and methods for protecting a device from destructive current conditions, such as overload current conditions and short circuit current conditions.

In accordance with other aspects of the invention, the systems and methods enable limiting the time of a destructive current condition through the device, and enable limiting the maximum current of a destructive current condition through the device.

These and other aspects and advantages of the invention will become apparent from the following detailed description and the accompanying drawing, which illustrates by way of example the features of the invention.

### BRIEF DESCRIPTION OF THE DRAWINGS

The FIGURE is a block circuit diagram of a destructive current conditions protective system and method of the present invention.

### DETAILED DESCRIPTION OF THE PREFERRED EMBODIMENTS

Referring to the drawing, the FIGURE, the system 10 enables protecting a device from destructive current conditions. The destructive current conditions which the system 10 protects the device from include overload current conditions and short circuit current conditions.

The device to be protected includes a controller 12, which includes switching components, and loads 14, driven by the controller 12. The controller 12 controls processes of the loads 14. The controller 12 comprises a fast speed device controller. The device to be protected by the system 10 may comprise an end user application device.

The controller switching components include maximum power ratings. System 10 prevents destructive current conditions from exceeding the maximum power ratings of the controller switching components. The controller switching components include maximum power ratings, and the system 10 prevents destructive current conditions from exceeding the maximum power ratings of the controller switching components. The reported current values in the time limiting element 16 and the maximum current limiting element 18 are specified so as not to exceed the maximum power ratings of the controller switching components.

System 10 includes a time limiting element 16 for limiting the time of a destructive current condition through the device, and a maximum current limiting element 18 for limiting the maximum current of a destructive current condition through the device. The time limiting element 16 comprises a current sensing element. The current sensing element comprises a fast-speed current sensing element. Maximum current limiting element 18 comprises a resistive element, which may comprise a shunt resistive element. The shunt resistive element limits short circuit current. The shunt resistive element may comprise a shunt resistor.

The device protected by system 10 includes a circuit which includes a power input 20, and a destructive current condition protecting module 22 connected to the controller 12. Controller 12 includes a current sensing input 24, a main power input 26, and power outputs 28 connected to the loads 14. System 10 continuously monitors and reports the current value of the time limiting element 16 and the maximum current limiting element 18 as the current sensing input 24 to the controller 12. System 10 prevents current which exceed its maximum allowed ratings from passing through the device switching components.

The protected device includes a connector 22 for connecting to a power source, the loads 14, a high voltage component, and the controller 12 which includes switching components for driving the loads 14. System 10 protects against destructive current conditions in the device which may be caused by failure of the high voltage component of the device. The system 10 protects the controller switching components from destructive current conditions. System 10 protects the controller switching elements from destructive current conditions exceeding the maximum power ratings of the controller switching elements.

Current sensing element 16 measures and monitors the current though the power source 20, reports the results to the device controller 12, and loops the value of the measured and monitored current to the device controller 12 driving the device loads 14. Device controller 12 decides whether to continue to operate or shut off all the power to the loads 14 that the controller 12 is driving. Controller 12 makes decisions whether to continue to operate or shut off all power to the loads 14 based on reported current values.

In operation, for example, the device to be protected from destructive current conditions by system 10 may comprise an end user device such as a commercial coffee maker. The device is connected to a power source through the power input 20, the loads are driven by switching components in the controller 12, and the device includes a high voltage component.

The destructive current conditions against which the device is to be protected by the system includes overload current conditions and short circuit current conditions. The destructive current conditions may be caused by failure of the high voltage component of the device.

The switching components of the controller 12 include maximum power ratings, and the system 10 prevents destructive current conditions from exceeding the maximum power ratings of the controller switching components. The system protects the controller switching components from destructive current conditions.

The current sensing time limiting element 16 measures and monitors the current though the power source 20, reports the results to the device controller 12, and loops the value of the measured and monitored current to the device controller 12 for driving the device loads 14. The device controller 12 decides whether to continue to operate or shut off all the power to the loads 14 that the controller 12 is driving.

The system 10 continuously monitors and reports the current value of the time limiting element 16 and the maximum current limiting element 18 as the current sensing input 24 to the controller 12. The controller makes decisions whether to continue to operate or shut off all power to the loads 14 based on the reported current values.

The system 10 limits the time of a destructive current condition through the device to be protected, through the time limiting element 16, which is a current sensing element, and limits the maximum current of a destructive current condition through the device, through the maximum current limiting element 18, which comprises a resistive element. The shunt resistive element, which may comprise a shunt resistor, limits short circuit current. Also, the reported current values in the time limiting element 16 and the maximum current limiting element 18 are prevented by system 10 from exceeding the maximum power ratings of the controller switching components and from passing through the system 10.

While the particular protective systems and methods as shown and disclosed in detail herein are fully capable of obtaining the objects and providing the advantages previously stated, it is to be understood that it is merely illustrative of the presently preferred embodiment of the invention, and that no limitations are intended to the details of construction or design shown herein.

We claim:

1. A system for protecting a device from destructive current conditions, wherein the device includes a controller which includes switching components, and loads driven by the controller, and wherein the controller controls processes of the loads, comprising:
an element for limiting the time of a destructive current condition through the device; and
an element for limiting the maximum current of a destructive current condition through the device.

2. A system as in claim 1, wherein the device includes a connector for connecting to a power source, a load, a high voltage component, and a controller which includes switching components for driving the load.

3. A system as in claim 1, wherein the time limiting element comprises a current sensing element.

4. A system as in claim 1, wherein the maximum current limiting element comprises a resistive element.

5. A system as in claim 1, wherein the device protected by the protecting system comprises an end user application device.

6. A system as in claim 1, wherein the destructive current condition comprises an overload current condition.

7. A system as in claim 1, wherein the destructive current condition comprises a short circuit current condition.

8. A system as in claim 1, wherein the device protected by the protecting system comprises a commercial coffee maker.

9. A system as in claim 2, wherein the device includes a circuit including a power input, and a destructive current condition protecting module connected to the controller, and wherein the controller includes a current sensing input, a main power input, and power outputs connected to the loads.

10. A system as in claim 2, wherein the controller switching components include maximum power ratings, and the system prevents destructive current conditions from exceeding the maximum power ratings of the controller switching components.

11. A system as in claim 2, wherein the controller switching components include maximum power ratings, and the reported current values in the time limiting element and the maximum current limiting element cannot exceed the maximum power ratings of the controller switching components.

12. A system as in claim 2, wherein the device controller comprises a fast speed device controller.

13. A system as in claim 2, wherein the destructive current condition is caused by failure of the high voltage component of the device.

14. A system as in claim 2, wherein the system protects the controller switching components from destructive current conditions.

15. A system as in claim 2, wherein the current sensing element measures and monitors the current though the power source, reports the results to the device controller, and loops the value of the measured and monitored current to the device controller driving the device load, and wherein the device controller decides whether to continue to operate or shut off all the power to the load that the controller is driving.

16. A system as in claim 3, wherein the system continuously monitors and reports the current value of the time limiting element and the maximum current limiting element as the current sensing input to the controller.

17. A system as in claim 3, wherein the controller makes decisions whether to continue to operate or shut off all power to the loads based on reported current values.

18. A system as in claim 3, wherein the current sensing element comprises a fast-speed current sensing element.

19. A system as in claim 4, wherein the maximum current limiting element comprises a shunt resistive element.

20. A system as in claim 16, wherein the system prevents current which exceed its maximum allowed ratings from passing through the device switching components.

21. A system as in claim 19, wherein the shunt resistive element limits short circuit current.

22. A system as in claim 19, wherein the shunt resistive element comprises a shunt resistor.

23. A system as in claim 20, wherein the protecting system protects the controller switching components from destructive current conditions exceeding the maximum power ratings of the controller switching elements.

24. A method for protecting a device from destructive current conditions in a system for protecting a device from destructive current conditions, wherein the device includes a controller which includes switching components, and loads driven by the controller, wherein the controller controls processes of the loads, and wherein the method comprises:
limiting the time of a destructive current condition through the device, through the time limiting element; and
limiting the maximum current of a destructive current condition through the device, through the maximum current limiting element.

25. A method as in claim 24, wherein the device includes a connector for connecting to a power source, a load, a high voltage component, and a controller which includes switching components for driving the load, and wherein the method further includes driving the load, through the controller switching components.

26. A method as in claim 24, wherein the time limiting element in the system comprises a current sensing element, and wherein the method further includes sensing the current through the current sensing element.

27. A method as in claim 24, wherein the maximum current limiting element comprises a resistive element, and wherein the method further includes the limiting the maximum current through the resistive element.

28. A method as in claim 24, wherein the device in the system protected by the protecting system comprises an end user application device, and wherein the method further includes protecting the end user application device through the protecting system.
